(19) United States
(12) Patent Application Publication
(10) Pub. No.: US 2025/0182817 A1
(43) Pub. Date: Jun. 5, 2025

(54) MULTI-PORT MEMORY DEVICE WITH BUILT-IN CONFIGURABLE LOGIC BLOCK TO PERFORM A PARALLEL COMPUTING OPERATION

(71) Applicant: Rambus Inc., San Jose, CA (US)

(72) Inventors: Dongyun Lee, Sunnyvale, CA (US); Mark D. Kellam, Siler City, NC (US)

(21) Appl. No.: 18/943,434

(22) Filed: Nov. 11, 2024

Related U.S. Application Data
(60) Provisional application No. 63/604,731, filed on Nov. 30, 2023.

(51) Int. Cl. G11C 11/4096

(52) U.S. Cl. CPC G11C 11/4096

(57) ABSTRACT

Technologies for multi-port memory devices with built-in configurable logic blocks are described. A dynamic random access memory (DRAM) device includes one or more stacks of memory dies, and a base die having at least two ports. Each of the at least two ports includes one or more sub-ports. The DRAM device includes a configurable logic block on the base die to perform an operation on data from the one or more sub-ports or the one or more stacks of memory dies.

### RELATED APPLICATIONS

This application claims the benefit of U.S. Provisional Application No. 63/604,731, filed Nov. 30, 2023, the entire contents of which is incorporated herein by reference.

### BACKGROUND

Modern computer systems generally include a data storage device, such as a memory component or device. The memory component may be, for example, a random-access memory (RAM) or a dynamic random-access memory (DRAM) device. The memory device includes memory banks made up of memory cells that a memory controller or memory client accesses through a command interface and a data interface within the memory device. The memory devices may be located on a memory module. The memory module may include one or more volatile memory devices.

Modern computer systems aggregate many graphics processing units (GPUs) in a hierarchical manner and interconnect them with a proprietary link. Data movement among GPUs becomes a bottleneck in reducing execution time and increases power consumption.

### BRIEF DESCRIPTION OF THE DRAWINGS

The present disclosure is illustrated by way of example, and not by way of limitation, in the figures of the accompanying drawings.

FIG. 1 is a block diagram of a computing system with four GPUs and multi-port memory devices as GPU connections between the GPUs according to at least one embodiment.

FIG. 2 is a block diagram of a dual-port memory device according to at least one embodiment.

FIG. 3 illustrates data flows in all-reduce operation using four GPUs and communication links between the GPUs according to at least one embodiment.

FIG. 4 illustrates data flows in an all-reduce operation with multi-port memory devices as GPU connections between the GPUs according to at least one embodiment.

FIG. 5 illustrates data flows in an all-reduce operation with multi-port memory devices as GPU connections between the GPUs according to at least one embodiment.

FIG. 6 illustrates data flows in an all-reduce operation with multi-port memory devices as GPU connections between the GPUs according to at least one embodiment.

FIG. 7 illustrates data flows in an all-reduce operation with multi-port memory devices as GPU connections between the GPUs in a closed ring according to at least one embodiment.

FIG. 8A is a block diagram of a memory device with one memory stack and two ports according to at least one embodiment.

FIG. 8B is a block diagram of a memory device with one memory stack, two ports, and two sub-ports per port according to at least one embodiment.

FIG. 9 illustrates data flows in an all-reduce operation with a computing system having eight nodes and dual-port memory devices as high-bandwidth memory (HBM) connections between the eight nodes according to at least one embodiment.

FIG. 10 illustrates data flows in an all-reduce operation with a computing system with eight GPUs, dual-port memory devices as HBM channels between some nodes, and additional communication links between other nodes according to at least one embodiment.

FIG. 11 illustrates an expansion card with eight GPUs and dual-port memory devices as HBM connections between the eight GPUs according to at least one embodiment.

FIG. 12 illustrates a rack with multiple servers with multiple expansion cards according to at least one embodiment.

FIG. 13 is a flow diagram of a method for performing an operation on data received at a multi-port memory device according to at least one embodiment.

### DETAILED DESCRIPTION

Technologies for multi-port memory devices with built-in configurable logic blocks are described. The following description sets forth numerous specific details, such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or presented in simple block diagram format to avoid obscuring the present disclosure unnecessarily. Thus, the specific details set forth are merely exemplary. Particular implementations may vary from these exemplary details and still be contemplated to be within the scope of the present disclosure.

As described above, modern computer systems aggregate many GPUs in a hierarchical manner and interconnect them with a proprietary link (e.g., InfiniBand, Ethernet, or the like). Data movement among GPUs becomes a bottleneck in reducing execution time and increases power consumption. For a typical system with eight GPUs and all-to-all connections between the eight GPUs, communication between GPUs takes a significant amount of the time to execute a parallel computing operation (also called a distributed computing operation). The communication between GPUs also consumes significant energy. For an all-reduce operation (“AllReduce”), the amount of time may be expressed as 2*X/B, where X is an amount of data and B is per-chip bandwidth. The energy consumption for the all-reduce operation may be expressed as 2*N*P*X, where X is the amount of data, N is the number of GPUs, and P is the data movement energy, expressed as an energy unit of picojoules per bit (pJ/b), to move data between GPUs. A proprietary link may operate at 450 GB/sec (unidirectional) with approximately 4 pJ/b, or a High Bandwidth Memory Input/Output (HBM I/O) may operate at 1 TB/s per device with 1 pJ/b.

Aspects and embodiments of the present disclosure address the above and other deficiencies by providing a multi-port memory device with built-in configurable logic blocks and configurable connections between ports and memory stacks. These memory devices may be coupled between GPUS and serve as a high-bandwidth communication channel between GPUs. The memory device may reduce time and energy for parallel computing operations (or distributed computing operations), such as those used in machine learning/artificial intelligence (ML/AI) algorithms involving multiple GPUs. For example, an ML/AI algorithm may use an all-reduce operation (Allreduce). The configurable logic block may be a reduce function block that performs the all-reduce operation. Aspects and embodiments of the present disclosure may provide a connection topology that increases the bandwidth per chip and reduces energy consumption (reduces pJ/b) between GPUs. Aspects and embodiments of the present disclosure may provide multi-port memory devices as high-bandwidth communication channels between the GPUs. A multi-port memory device may have a base die that is a logic die used for advanced logic processing. Unlike conventional systems, aspects and embodiments of the present disclosure consider energy consumption (pJ/b) to access memory in the GPU network design. Aspects and embodiments of the present disclosure may re-architecture an HBM base die to provide a wide, energy-efficient communication channel between GPUs and logical functions to optimize data movement. Aspects and embodiments of the present disclosure may provide better performance in terms of time and energy. Aspects and embodiments of the present disclosure may provide a scalable solution.

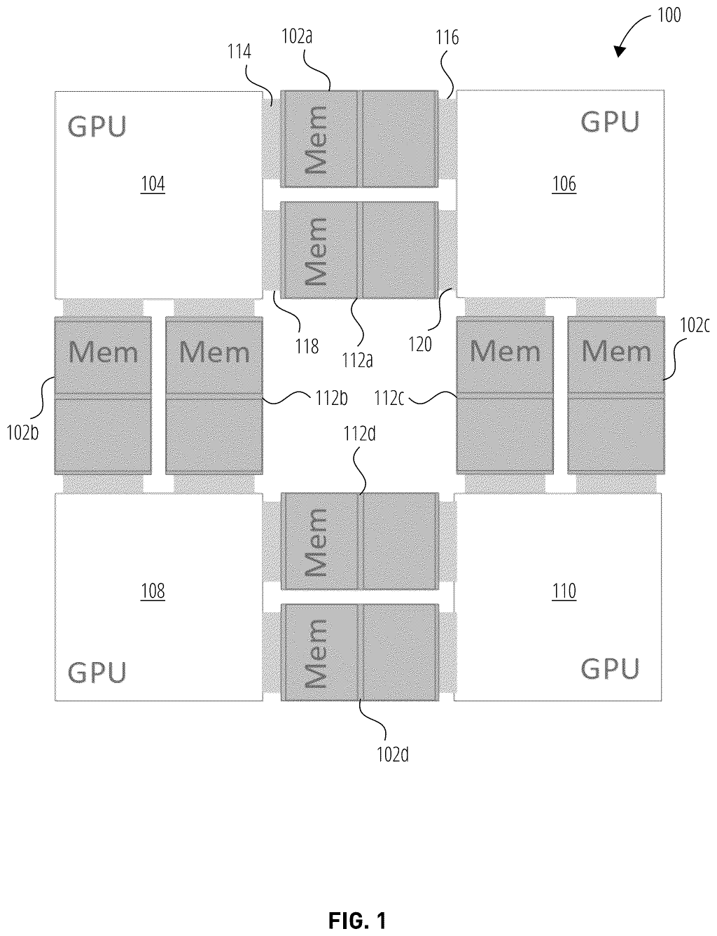

FIG. 1 is a block diagram of a computing system 100 with four GPUs 104-110 and multi-port memory devices 102a-d, 112a-d as GPU connections between the GPUs according to at least one embodiment. Instead of using proprietary communication links between GPUs 104-110, memory channels with multi-port memory devices may provide high-bandwidth communication channels between GPUs 104-110. The multi-port memory devices may reduce time and energy for operations involving multiple GPUs, such as for an all-reduce operation of an ML/AI algorithm. More specifically, a first GPU 104 is coupled to a second GPU 106 using a first GPU connection with a dual-port memory device 102a and a second GPU connection with a dual-port memory device 112a. The first GPU connection (or first memory channel) operates as a first communication interconnect between the first GPU 104 and the second GPU 106. The first GPU 104 and the second GPU 106 may access memory arrays of the dual-port memory device 102a in the first memory channel, as well as send or receive data from one another without accessing the memory arrays. The dual-port memory device 102a includes a first port 114 coupled to the first GPU 104 and a second port 116 coupled to the second GPU 106. Similarly, the second GPU connection (or second memory channel) operates as a second communication interconnect between the first GPU 104 and the second GPU 106. The dual-port memory device 112a includes a third port 118 coupled to the first GPU 104 and a fourth port 120 coupled to the second GPU 106. The first GPU 104 and the second GPU 106 may access memory arrays of the dual-port memory device 112a in the second memory channel, as well as send or receive data from one another without accessing the memory arrays. Similarly, the first GPU 104 is coupled to the third GPU 108 via two GPU connections with dual-port memory devices. The second GPU 106 is coupled to the fourth GPU 110 via two GPU connections with dual port memory devices. The third GPU 108 and the fourth GPU 110 are coupled via two GPU connections with multi-port memory devices in a similar manner. In at least one embodiment, the first GPU connection with dual-port memory devices 102a and 112a may operate at 2 terabytes (TB) per second (TB/sec): 1 TB/sec for the first port 114 and 1 TB/sec for the third port 118. The other ports may achieve similar transfer speeds. Similarly, the first GPU 104 is coupled to a third GPU 108 using a third GPU connection with a dual-port memory device 102b and a fourth GPU connection with a dual-port memory device 112b. Similarly, the second GPU 106 is coupled to a fourth GPU 110 using a fifth GPU connection with a dual-port memory device 102c and a sixth GPU connection with a dual-port memory device 112c. Similarly, the third GPU 108 is coupled to the fourth GPU 110 using a seventh GPU connection with a dual-port memory device 102d and an eighth GPU connection with a dual-port memory device 112d.

In at least one embodiment, the dual-port memory device 102a (or 102b-d or 112a-d) is a dynamic random access memory (DRAM) device with two ports, each port including one or more sub-ports. The dual-port memory device 102a includes one or more stacks of memory die and a base die having the first port 114 and the second port 116 and configurable routing and functional blocks. The configurable routing circuitry on the base die may route data from each of the sub-ports or each of the stacks of memory dies. The configurable routing circuitry may configure connections between ports and memory stacks (e.g., the memory array). Not only does the dual-port memory device 102a operate as a high-bandwidth communication channel between GPUs, but the dual-port memory device 102a reduces time and energy for an ML/AI algorithm involving multiple GPUs. The configurable logic blocks may do “reduce” function blocks that may contribute to an all-reduce operation, including a reduce-scatter and all-gather operations, in an ML/AI algorithm. For example, there are large amounts of data movement in training an ML model. The dual-port memory device 102a may reduce the time and energy for training the ML model. For example, there may be multiple training phases in which a network's weights may be used for computations, then modified and used again. Then, the results may be averaged. The model weights and computations may be spread across multiple GPUs, so the weights may be scattered to the multiple GPUs for computations, and the results may be gathered back to compute the average. Alternatively, the model may be trained using other parallel computing operations or distributed computing operations. Similarly, the dual-port memory device 102a may reduce the time and energy for using the ML model during inference. The base die's reduce function block is configurable to determine a minimum, a maximum, a medium, an average, or the like. Other functions may be added to the reduce function block, such as pattern matching, thresholding, scaling, limiting, or the like. The dual-port memory device 102a may have many channels and the memory channels may be grouped into sub-ports and work in lockstep. The grouping is configurable to accommodate different models and data sizes.

In at least one embodiment, each of the first port 114 and the second port 116 includes one or more sub-ports. Each sub-port has one or more channels operating in lockstep. Each of the one or more stacks of the dual-port memory device 102a is accessible by each of the first port 114 and the second port 116. The dual-port memory device 102a includes one or more configurable logic blocks on the base die. In at least one embodiment, the number of sub-ports is configurable. The number of sub-ports of the device may be configured before deployment. The configurable logic blocks may perform an operation on data from the sub-ports or the stacks of memory dies. In at least one embodiment, the operation is a parallel computing operation, a distributed computing operation, a parallel and distributed computing operation, or the like. In at least one embodiment, the operation collectively performs an all-reduce operation, including a reduce-scatter operation and an all-gather operation as described herein. In at least one embodiment, the configurable logic block may perform at least one of a reduce operation, an all-reduce operation, a reduce-scatter operation, a gather operation, an all-gather operation, a scatter operation, a broadcast operation, a barrier operation, a prefix sum operation, an all-to-all operation, a reduce-all operation, a scatter-gather operation, a collective communication operation, a parallel prefix operation, or a map-reduce operation. In at least one embodiment, the configurable logic block may perform at least a portion of an all-reduce operation, including a reduce-scatter operation and an all-gather operation. In at least one embodiment, the operation performed by configurable logic blocks is configurable.

In at least one embodiment, the configurable logic blocks are located on a base die of the dual-port memory device 102a. The base die with the configurable logic blocks and the multiple ports (e.g., first port 114 and second port 116) may provide a wide communication channel between the first GPU 104 and the second GPU 106. The logical functions of the configurable logic blocks may optimize data movement between the first GPU 104 and the second GPU 106. This architecture may enable better performance in terms of time and energy and provide a scalable solution.

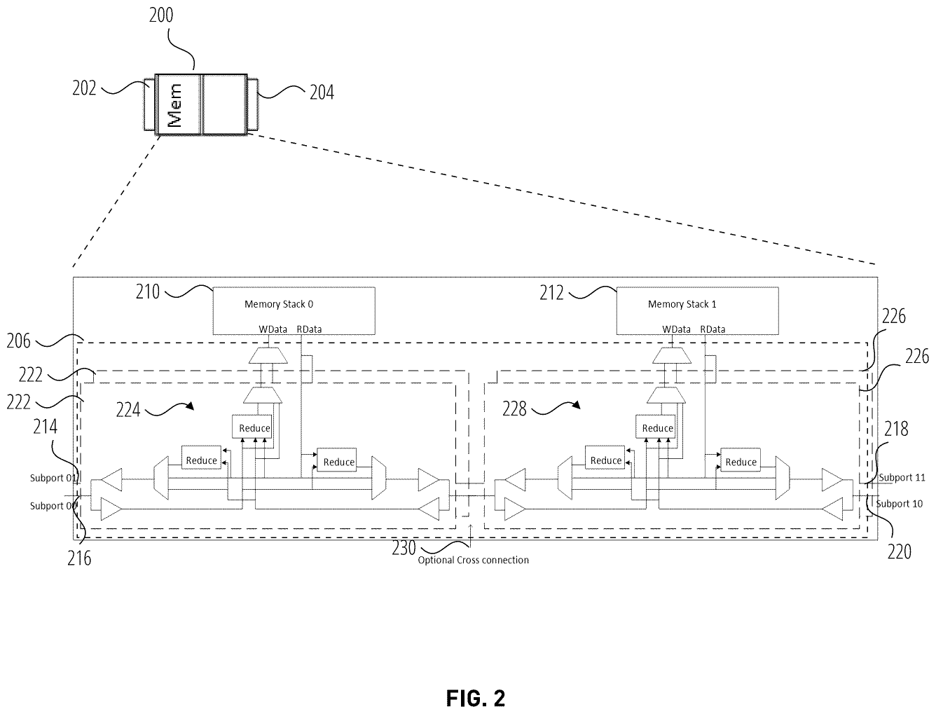

In at least one embodiment, the dual-port memory device 112 (e.g., 112a-d) and other dual-port memory devices (e.g., 102b-d) between the other GPUs may include one or more stacks of memory dies and a base die similar to the dual-port memory device 102a. Additional details of the dual-port memory device are described below with respect to FIG. 2.

FIG. 2 is a block diagram of a dual-port memory device 200 according to at least one embodiment. The dual-port memory device 200 may be used as part of a GPU connection between two GPUs, as described above with respect to FIG. 1. The dual-port memory device 200 includes a base die 206, a first memory stack 210, and a second memory stack 212. It should be noted that the base die 206 is represented as four hashed blocks, each block corresponding to one of the fourth sub-ports. The base die 206 is coupled to the first port 202, which may be coupled to a first GPU (not illustrated in FIG. 2). The base die 206 is coupled to the second port 204, which may be coupled to a second GPU (not illustrated in FIG. 2). The dual-port memory device 200 may be configured to include two ports. The dual-port memory device 200 may be configured to include two ports, where each port has multiple sub-ports, such as illustrated in FIG. 2. In particular, the first port 202 of the base die 206 may be programmably divided into a first sub-port 214 and a second sub-port 216. The second port 204 may be programmably divided into a third sub-port 218 and a fourth sub-port 220. Although two sub-ports are illustrated in FIG. 2, the first port 202 and the second port 204 may each include one or more sub-ports. In other words, the base die 206 and the second base die may each include one or more sub-ports, each having configurable routing circuitry and configurable logic blocks. Each of the first sub-port 214 and second sub-port 216 may access the first memory stack 210 and the second memory stack 212. Each of the third sub-port 218 and the fourth sub-port 220 may access the second memory stack 212 and the first memory stack 210. Each of the first sub-port 214 and second sub-port 216 may access each other, as well as the third sub-port 218 and the fourth sub-port 220. Each of the third sub-port 218 and the fourth sub-port 220 may access each other and the first sub-port 214 and the second sub-port 216. The sub-ports may access each other and each of the memory stacks using configurable routing circuitry. For example, the first sub-port 214 may access the first memory stack 210 using first configurable routing circuitry 222. The first configurable routing circuitry 222 is represented in FIG. 2 as the two overlapped blocks, one for each sub-port. The first sub-port 214 may access the second memory stack 212 using first configurable routing circuitry 222 and second configurable routing circuitry 226. Similarly, the third sub-port 218 may access the second memory stack 212 using the second configurable routing circuitry 226. The third sub-port 218 may access the first memory stack 210 using the second configurable routing circuitry 226 and the first configurable routing circuitry 222. As described herein, the base die 206 and the second base die 208 may perform operations on the data being moved between sub-ports and the memory stacks using configurable logic blocks. As illustrated in FIG. 2, the base die 206 includes configurable logic blocks 224 (labeled “reduce”). The configurable logic blocks 224 may perform a reduce operation on data being moved to or from the first memory stack 210. Similarly, the second base die 208 includes configurable logic blocks 228 (labeled “reduce”). The configurable logic blocks 228 may perform a reduce operation on data being moved to or from the second memory stack 212. The configurable logic blocks 224 may also perform the reduce operation on data being moved to or from the second memory stack 212, and the configurable logic blocks 228 may also perform the reduce operation on data being moved to or from the first memory stack 210, respectively.

In another embodiment, the dual-port memory device 200 includes a first base die and a second base die. For example, the first base die may include the first configurable routing circuitry 222 for the first sub-port 214 and the second sub-port 216, and the second base die may include the second configurable routing circuitry 226 for the third sub-port 218 and the fourth sub-port 220.

In at least one embodiment, the dual-port memory device 200 includes a cross connection 230 between the multiple sub-ports of the first port 202 and the second port 204. The cross connection 230 may be used to connect the first sub-port 214 with the fourth sub-port 220 and the second memory stack 212. The cross connection 230 may be used to connect the second sub-port 216 with the third sub-port 218 and the second memory stack 212.

As described above, the sub-ports may access each other and each of the memory stacks using configurable routing circuitry. In particular, the first configurable routing circuitry 222 may include multiple bi-directional drivers and multiple multiplexers to create different paths between the sub-ports and memory stacks. For example, data received at the first sub-port 214 may be driven by a first driver to one or more multiple paths. A first path is between the first driver and a first configurable logic block of the configurable logic blocks 224. A second path bypasses the first configurable logic block to access the first memory stack 210. A third path is between the first driver and a second configurable logic block before being driven by a second driver to the third sub-port 218. A fourth path bypasses the second configurable logic block 226 to be driven by the second driver to the third sub-port 218. The multiplexers may be used to select the appropriate data paths for data based on the source and destination of the data.

Similarly, data flowing from the first memory stack 210 may be directed to any of the sub-ports using different paths with or without the configurable logic blocks 224 using the multiplexers. Similarly, the second configurable routing circuitry 226 may include bi-directional drivers and multiplexers to create different paths with or without the configurable logic blocks 228. As described herein, the configurable logic blocks of the dual-port memory device 200 may be used to perform a parallel computing operation. For example, the configurable logic block may perform a reduce operation, an all-reduce operation, a reduce-scatter operation, a gather operation, an all-gather operation, a scatter operation, a broadcast operation, a barrier operation, a prefix sum operation, an all-to-all operation, a scatter-gather operation, a collective communication operation, a parallel prefix operation, a map-reduce operation, or the like. These operations may also be referred to as functions.

In general, the reduce operation may combine data from multiple processes into a single result, typically using an associative and commutative operation (e.g., sum, product). The all-reduce operation may be similar to the reduce operation but distributes the result to all processes, ensuring that all processes have the same result. The reduce-scatter operation may combine data from multiple source processes into multiple results and distribute them among the destination processes. The gather operation may collect data from multiple source processes into a single destination process. The all-gather operation may gather data from all processes and distribute the combined data to all processes, ensuring that each process has the full dataset. The scatter operation may distribute data from a single source process to multiple destination processes. The broadcast operation may send data from one process to all other processes, ensuring that all processes receive the same data. The barrier operation may synchronize all processes, ensuring that no process proceeds until all processes have reached the barrier. The prefix sum operation (scan) may compute the prefix sum (cumulative sum) of a sequence of values across processes. Each process receives the partial sum of values up to its position. The all-to-all operation may exchange data between all pairs of processes. Each process sends data to all others and receives data from all others. The reduce-all operation (All-Reduce) may perform a reduction operation (e.g., sum) across all processes and distribute the result to all processes. The scatter-gather operation may combine the scatter and gather operations. Data is scattered from one set of processes to another and then gathered at the destination processes. The collective communication operations may coordinate communication among a group of processes. They are often used to efficiently perform operations that require data exchange or synchronization among multiple processes. The parallel prefix operation (scan) may compute prefix operations like prefix sum or prefix product in a parallel manner, often used in algorithms and parallel processing. The map-reduce operation may have two phases: mapping (data distribution) and reducing (aggregation) in a programming model and framework for processing large datasets in parallel. These operations may be building blocks for parallel and distributed algorithms and are commonly used in various parallel and distributed computing environments, including message-passing libraries, parallel programming frameworks, and distributed computing platforms. The choice of operation depends on the specific requirements of the parallel or distributed task at hand.

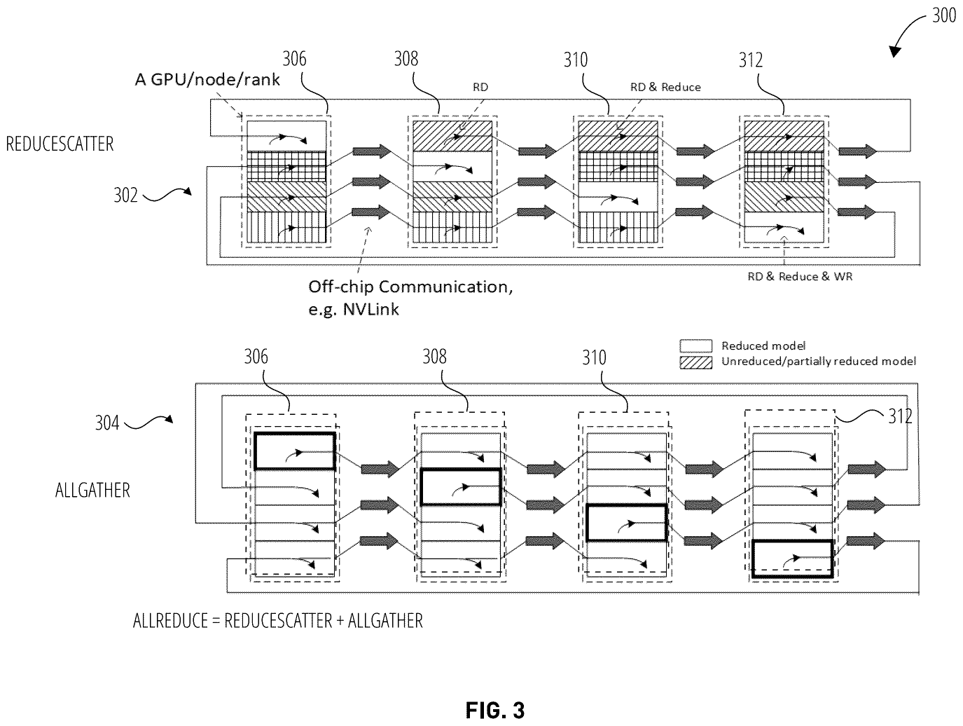

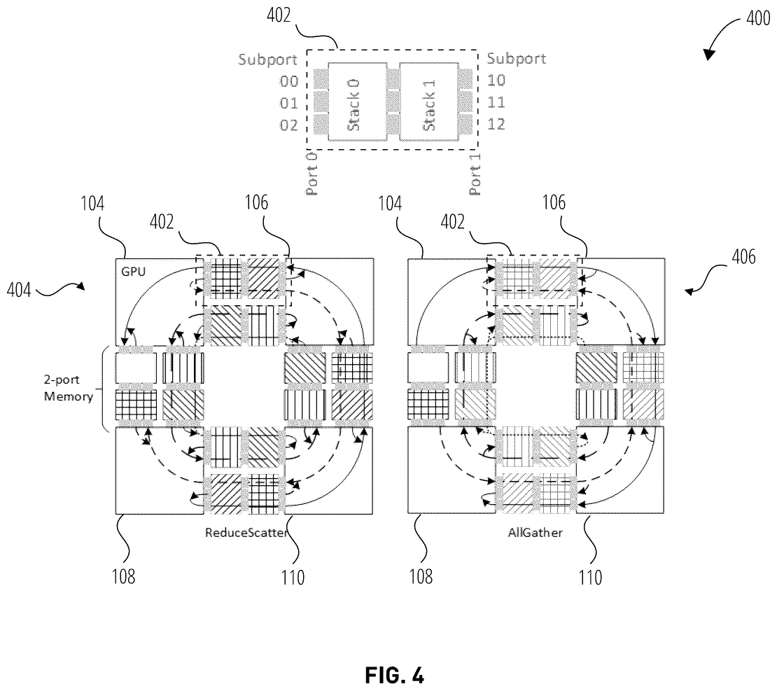

In at least one embodiment, the configurable logic block may perform at least a portion of an all-reduce operation, including a reduce-scatter operation and an all-gather operation. Details of an all-reduce operation using four GPUs and communication links between the GPUs are described below with respect to FIG. 3. Performing the all-reduce operations using the multi-port memory devices as GPU connections (communication interconnects and memory channels) are described below with respect to FIG. 4 to FIG. 7.

FIG. 3 illustrates data flows in an all-reduce operation 300 using four GPUs and communication links between the GPUs according to at least one embodiment. The all-reduce operation 300 may include a reduce-scatter operation and an all-gather operation. The all-reduce operation 300 shows the data flows in a reduce-scatter operation 302 and the data flows in an all-gather operation 304 separately. As an example, FIG. 3 illustrates four GPUs/nodes, ranks of an open ring. The closed ring may shorten time but may consume more power. The memory buffer read and write operations may consume significant power. As described herein, the reduce-scatter operation 302 may combine data from multiple source processes into a result (e.g., sum) to a GPU. The all-gather operation may gather data from the GPU and distribute the combined data to all processes, ensuring that each process has the full dataset.

In the reduce-scatter operation 302, a first GPU 306 may read a first portion of the data and pass the first portion to the second GPU 308 over an off-chip communication link. The second GPU 308 may read a second portion of the data and perform a reduce operation with the first and second portions. The second GPU 308 may send the reduced data to the third GPU 310. The third GPU 310 may read a third portion of the data and perform a reduce operation with the reduced data and the third portion. The third GPU 310 may send the reduced data to the fourth GPU 312. The fourth GPU 312 may read a fourth portion of data, perform a reduce operation to combine the reduced data with the fourth data, and write the reduced data to memory. The four GPUs may read, read-reduce, and read-reduce-write other portions of the data at the respective GPUs, as illustrated in the reduce-scatter operation 302. As described above, using the communication links between the GPUs may result in multiple read and write operations to memory that consume significant power and time. Using communication links between GPUs, as illustrated in FIG. 3, the amount of time for the all-reduce operation 300 may be expressed at T=2*X/B, where X is an amount of data and B is per-chip bandwidth. The energy consumption for the all-reduce operation 300 may be expressed as E=2*N*P*X, where X is the amount of data, N is the number of GPUs, and P is the data movement energy (pJ/b) to move data between GPUs.

There are multiple parameters to consider in assessing data flow performance in terms of power and time, such as set forth in the following Table 1.

TABLE 1

| | |
|---|---|
| X | Model Size |
| N | Number of Nodes |
| B_{C} | Communication Link Unidirectional Rate |
| B_{M} | HBM Unidirectional Rate |
| P_{C} | Energy for Communication Link Signaling |
| P_{M2} | Energy for 20 mm Trace Signaling |
| P_{M1} | Energy for 10 mm Trace Signaling |
| P_{M0} | Energy for 5 mm Trace Signaling |
| M | Number of Memory devices per Side |
| P_{MS} | Memory Stack Access Energy |

The multi-port memory devices may improve the performance of the all-reduce operation in time and power, as described below with respect to FIG. 4 to FIG. 7.

FIG. 4 illustrates data flows in an all-reduce operation 400 with multi-port memory devices as GPU connections between the GPUs according to at least one embodiment. In this embodiment, instead of communication links between the GPUs, the dual-port memory device 402 may be GPU connections between the GPUs. The dual-port memory device 402 may be a two-stack HBM having two access ports. Each access port is divided into three different sub-ports. In particular, the first port includes a first sub-port, a second sub-port, a third sub-port, and the second port includes a fourth sub-port, a fifth sub-port, and a sixth sub-port. Each sub-port has access to all memory cells of one stack (optionally, both stacks). Each sub-port may be configured to read, write, or pass data. The all-reduce operation 400 includes a reduce-scatter operation 404 and an all-gather operation 406. The data flows of the reduce-scatter operation 404 are illustrated on the left side of FIG. 4, and the data flows of the all-gather operation 406 are illustrated on the right side of FIG. 4. Using the dual-port memory devices 402 in the GPU connections between GPUs as illustrated in FIG. 4, the amount of time for the all-reduce operation 400 (i.e., time to run the algorithm) may be expressed as Tₐᵣ=T(ReduceScatter)+T(AllGather)=X*(N−1)/(M*N*B_{M})+X*(N−1)/(M*N*B_{M})=2*X*(N−1)/(M*N*B_{M}). The energy consumption (energy in data movement) for the all-reduce operation 400 may be expressed as Eₐᵣ=P_{M2}*2*(N−1)*X+(P_{MS}+P_{M0})*(2N+1)*X.

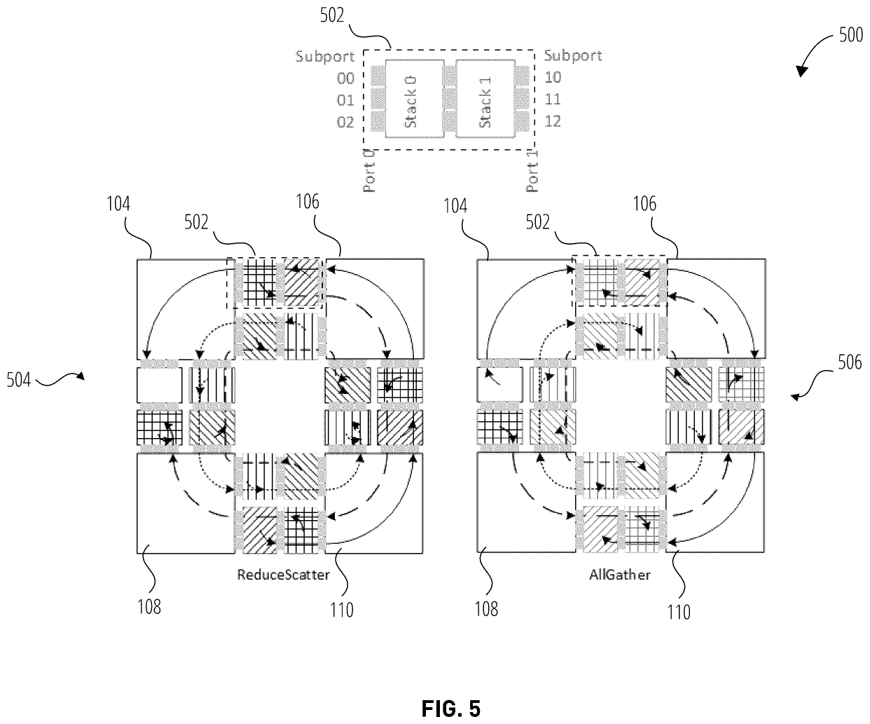

FIG. 5 illustrates data flows in an all-reduce operation 500 with multi-port memory devices as GPU connections between the GPUs according to at least one embodiment. In this embodiment, instead of communication links between the GPUs, the dual-port memory devices 502 may be GPU connections between the GPUs. The dual-port memory device 502 may be a two-stack HBM having two access ports and a reduce function (e.g., configurable logic blocks configured to perform the reduce function). Each access port is divided into three different sub-ports. Each sub-port has access to all memory cells of one stack (optionally, both stacks). The base die may include configurable logic blocks to perform the “reduce” function. Each sub-port may be configured to read, write, pass, read-pass, write-pass, read-reduce-pass, and read-reduce-write data. The all-reduce operation 500 includes a reduce-scatter operation 504 and an all-gather operation 506. The data flows of the reduce-scatter operation 504 are illustrated on the left side of FIG. 5, and the data flows of the all-gather operation 506 are illustrated on the right side of FIG. 5. Using the dual-port memory devices 502 in the GPU connections between GPUs as illustrated in FIG. 5, the amount of time for the all-reduce operation 500 (i.e., time to run the algorithm) may be expressed as Tₐᵣ=T(ReduceScatter)+T(AllGather)=X*(N−1)/(M*N*B_{M})+X*(N−1)/(M*N*B_{M})=2*X*(N−1)/(M*N*B_{M}). The energy consumption (energy in data movement) for the all-reduce operation 500 may be expressed as Eₐᵣ=2*{P_{M1}+P_{M2}*(N−2)}*X+(P_{MS}+P_{M0})*4*X+P_{MS}*(2N−3)*X.

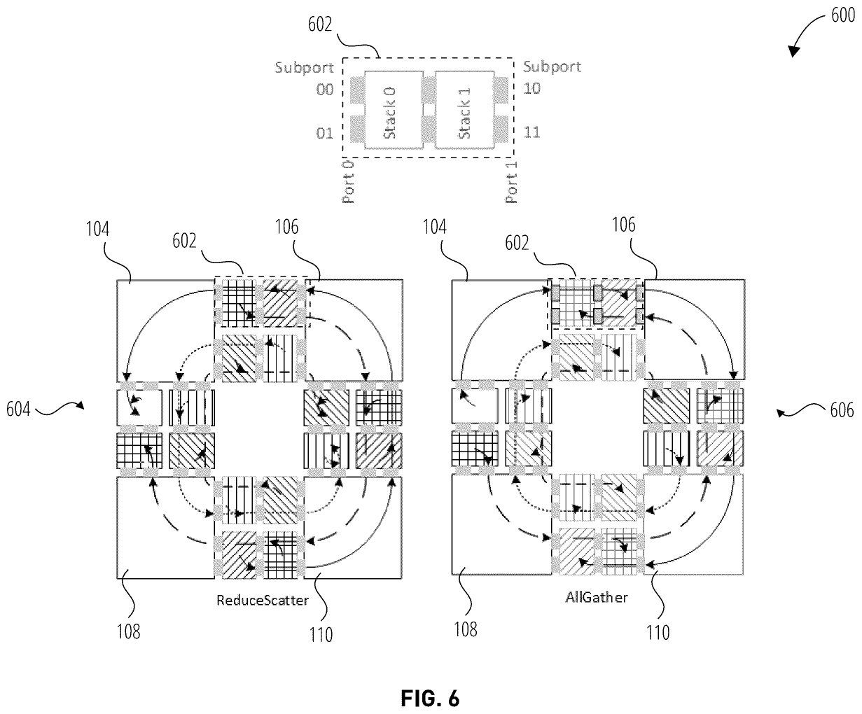

FIG. 6 illustrates data flows in an all-reduce operation 600 with multi-port memory devices as GPU connections between the GPUs according to at least one embodiment. In this embodiment, instead of communication links between the GPUs, the dual-port memory devices 602 may be GPU connections between the GPUs. The dual-port memory device 602 may be a two-stack HBM having two access ports, a reduce function (e.g., configurable logic blocks configured to perform the reduce function), and optimized sub-ports. Unlike the dual-port memory device 502, the dual-port memory device 602 includes two different sub-ports per access port. In particular, the first port includes a first sub-port and a second sub-port, and the second port includes a third sub-port and a fourth sub-port. Each sub-port has access to all memory cells of one stack (optionally, both stacks). The base die may include configurable logic blocks to perform the “reduce” function. Each sub-port may be configured to read, write, pass, read-pass, write-pass, read-reduce-pass, and read-reduce-write data. The all-reduce operation 600 includes a reduce-scatter operation 604 and an all-gather operation 606. The data flows of the reduce-scatter operation 604 are illustrated on the left side of FIG. 6, and the data flows of the all-gather operation 606 are illustrated on the right side of FIG. 6. Using the dual-port memory devices 602 in the GPU connections between GPUs as illustrated in FIG. 6, the amount of time for the all-reduce operation 600 (i.e., time to run the algorithm) may be expressed as Tₐᵣ=T(ReduceScatter)+T(AllGather)=X*(N−2)/(M*N*B_{M})+X*(N−2)/(M*N*B_{M})=2*X*(N−2)/(M*N*B_{M}). The energy consumption (energy in data movement) for the all-reduce operation 600 may be expressed as Eₐᵣ=2*{P_{M1}+P_{M2}*(N−2)}*X+(P_{MS}+P_{M0})*4*X+P_{MS}*(2N−3)*X.

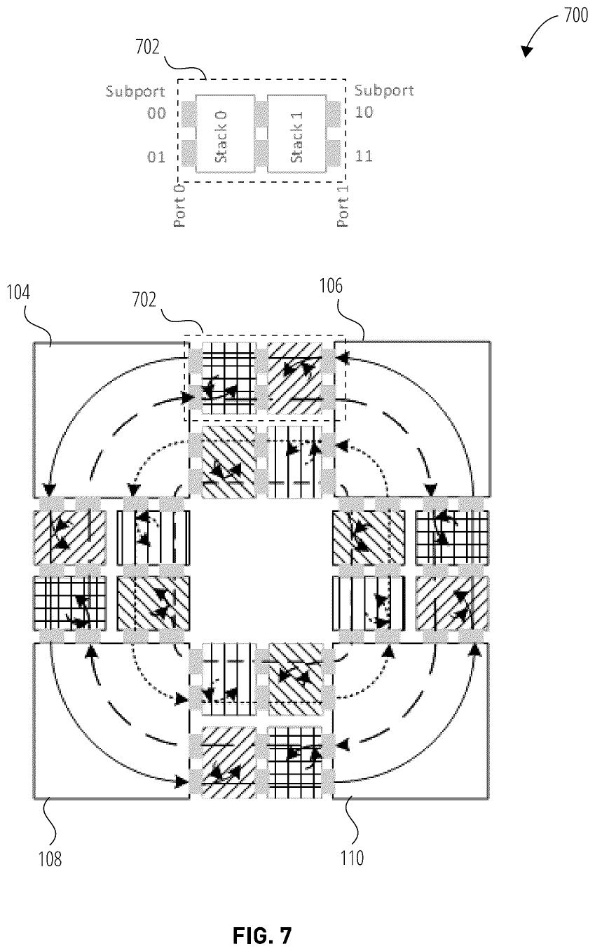

FIG. 7 illustrates data flows in an all-reduce operation 700 with dual-port memory devices 702 as GPU connections between the GPUs in a closed ring according to at least one embodiment. In this embodiment, instead of communication links between the GPUs, the dual-port memory devices 702 may be GPU connections between the GPUs. The dual-port memory device 702 may be a two-stack HBM having two access ports, a reduce function (e.g., configurable logic blocks configured to perform the reduce function), and optimized sub-ports. Unlike the dual-port memory device 502, the dual-port memory device 702 includes two different sub-ports per access port. Each sub-port has access to all memory cells of one stack (optionally, both stacks). The base die may include configurable logic blocks to perform the “reduce” function. Each sub-port may be configured to read, write, pass, read-pass, write-pass, read-reduce-pass, and read-reduce-write data. Using the dual-port memory devices 702 in the GPU connections between GPUs as illustrated in FIG. 7, the amount of time for the all-reduce operation 700 (i.e., time to run the algorithm) may be expressed as Tₐᵣ=X/(M*B_{M}). The energy consumption (energy in data movement) for the all-reduce operation 600 may be expressed as Eₐᵣ=P_{M2}*N*X+P_{MS}*2N*X.

Performance (time and energy) comparisons of various embodiments are set forth in the following Table 2. It is assumed that the model size is 96 GB, 8 GPUs are included, and 2 memory devices are shared between two GPUs.

TABLE 2
All-Reduce Performance(Time & Energy) Comparison Table

| | | Time [ms] | Energy [mJ] |
|---|---|---|---|
| Conv Ring | Open | 4.67 | 11088 |
| | Closed | 2.67 | 40320 |
| All-to-all | 2 Steps | 5.33 | 11856 |
| connections | 1 Step | 2.67 | 11520 |

| | | |
|---|---|---|
| FIG. 4 | 1.05 | 8400 |
| FIG. 5 | 1.05 | 7584 |
| FIG. 6 | 0.90 | 7584 |
| FIG. 7 | 0.60 | 6144 |

As set forth in Table 2, the proposed embodiments may result in approximately 4 times or greater reduction in time (>4× time) and approximately 2 times energy reduction compared to conventional approaches.

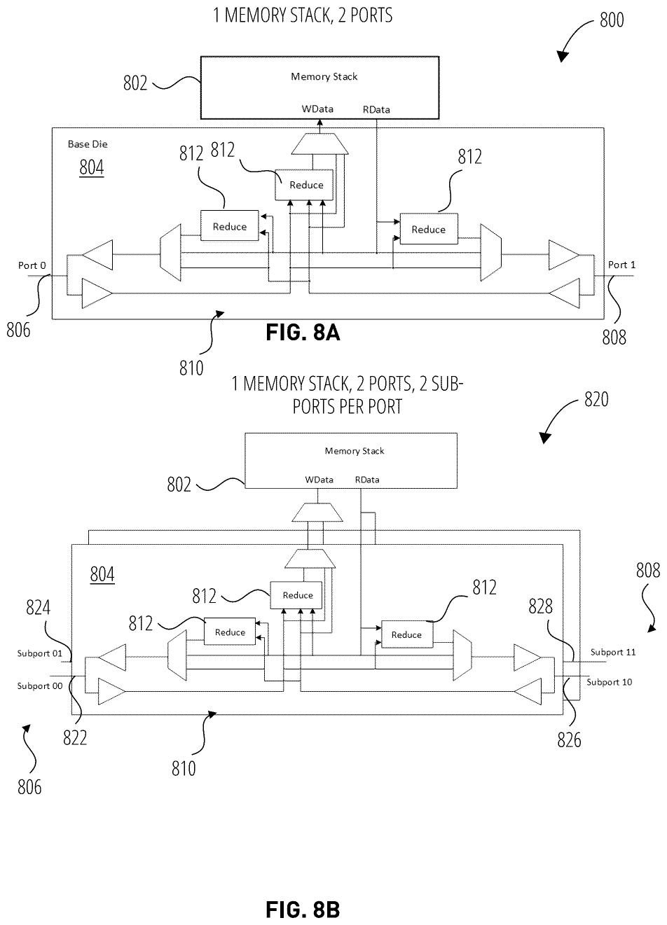

FIG. 8A is a block diagram of a memory device 800 with one memory stack 802 and two ports 806, 808, according to at least one embodiment. The memory device 800 includes a base die 804 having a first port 806, a second port 808, and first configurable logic circuitry 812. The memory stack 802 is accessible by the first port 806 and the second port 808 via the first configurable routing circuitry 810. The first configurable logic circuitry 812 is configured to perform an operation on data from at least one of the first port 806, the second port 808, or the memory stack 802. In at least one embodiment, the first configurable routing circuitry 810 includes three multiplexers to select paths between the first port 806, the second port 808, and the memory stack 802. Some of the paths include the first configurable logic circuitry 812. As illustrated in FIG. 8A, the first configurable logic circuitry 812 includes three reduce function blocks. The reduce function block may perform an all-reduce operation as described herein. The reduce function block is configurable to determine a minimum, a maximum, a medium, an average, or the like. Other functions may be added to the reduce function block, such as pattern matching, thresholding, scaling, limiting, or the like. As described herein, the memory device 800 may be used in a communication channel between two devices, such as two GPUs. The communication channel serves as a communication channel and a memory channel. As described herein, the memory channels may be grouped into multiple sub-ports and work in lockstep, as illustrated in FIG. 8B. The grouping is configurable to accommodate different models and data sizes.

FIG. 8B is a block diagram of a memory device 820 with one memory stack, two ports, and two sub-ports per port according to at least one embodiment. The memory device 820 is similar to the memory device 800 as noted with similar reference numbers, except the first port 806 includes a first sub-port 822 and a second sub-port 824, and the second first port 806 includes a third sub-port 826 and a fourth sub-port 828. The first sub-port 822 and the third sub-port 826 are coupled to the first configurable routing circuitry 810 and the first configurable logic circuitry 812. The second sub-port 824 and the fourth sub-port 828 are coupled to second configurable routing logic and second configurable logic circuitry (not illustrated in FIG. 8B). It should be noted that the two boxes illustrated in FIG. 8B (i.e., the base die 804 and the box behind the base die 804) can be implemented on a same die.

In a further embodiment, a memory device includes a first memory stack, a first base die, a second memory stack, and a second base die. The first base die and the second base die may be stacked with through-silicon-vias (TSVs) and packaged together with the memory stack(s). The first base die may include a first port, a second port, first configurable routing circuitry, first configurable logic circuitry, second configurable routing circuitry, and second configurable logic circuitry. The second base die may include a third sub-port with third configurable routing circuitry and third configurable logic circuitry and a fourth sub-port with fourth configurable routing circuitry and fourth configurable logic circuitry. The first memory stack is accessible by the first sub-port, the second sub-port, the third sub-port, and the fourth sub-port. The second memory stack is accessible by the first sub-port, the second sub-port, the third sub-port, and the fourth sub-port. The first configurable logic circuitry is configured to perform an operation on data from at least one of the first sub-port or the first memory stack. The second configurable logic circuitry is configured to perform the operation on data from at least one of the second sub-port or the first memory stack. The third configurable logic circuitry is to perform the operation on data from at least one of the third sub-port or the second memory stack. The fourth configurable logic circuitry is to perform the operation on data from at least one of the fourth sub-port or the second memory stack.

In another, the memory device includes the first memory stack, the second memory stack, and a single base die. That is, the base die includes the first sub-port, the second sub-port, the first and second configurable routing circuitry, and the first and second configurable logic circuitry, as described above. The base die also includes a third sub-port with third configurable routing circuitry and third configurable logic circuitry, and a fourth sub-port with fourth configurable routing circuitry and fourth configurable logic circuitry. The first memory stack is accessible by the first sub-port, the second sub-port, the third sub-port, and the fourth sub-port. The second memory stack is accessible by the first sub-port, the second sub-port, the third sub-port, and the fourth sub-port. The third configurable logic circuitry is to perform the operation on data from at least one of the third sub-port or the second memory stack. The fourth configurable logic circuitry is to perform the operation on data from at least one of the fourth sub-port or the second memory stack.

As described herein, the operation may be at least one of a reduce operation, an all-reduce operation, a reduce-scatter operation, a gather operation, an all-gather operation, a scatter operation, a broadcast operation, a barrier operation, a prefix sum operation, an all-to-all operation, a scatter-gather operation, a collective communication operation, a parallel prefix operation, a map-reduce operation, or the like.

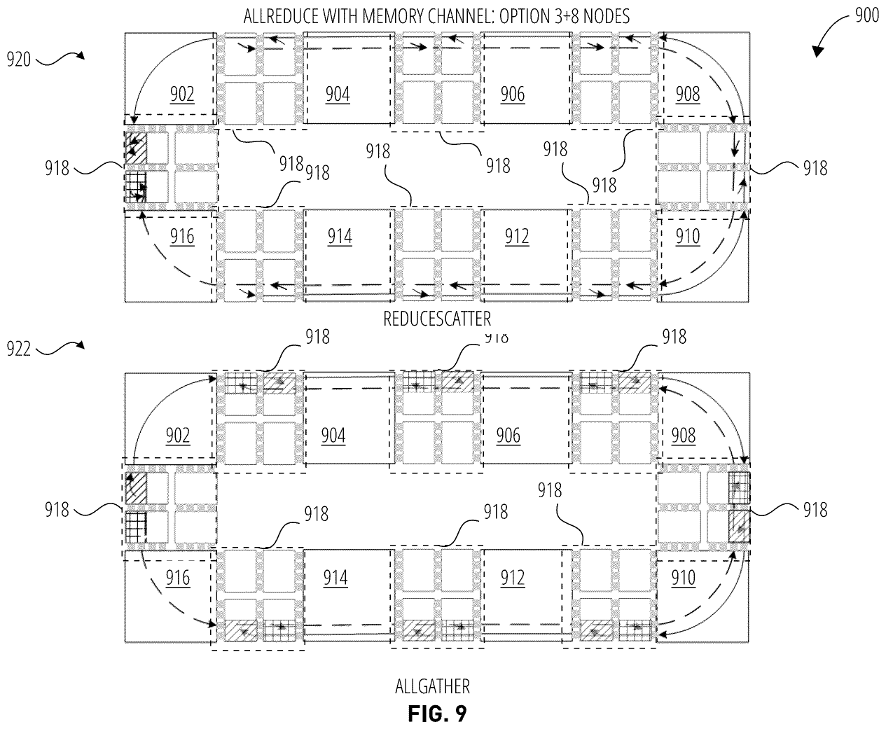

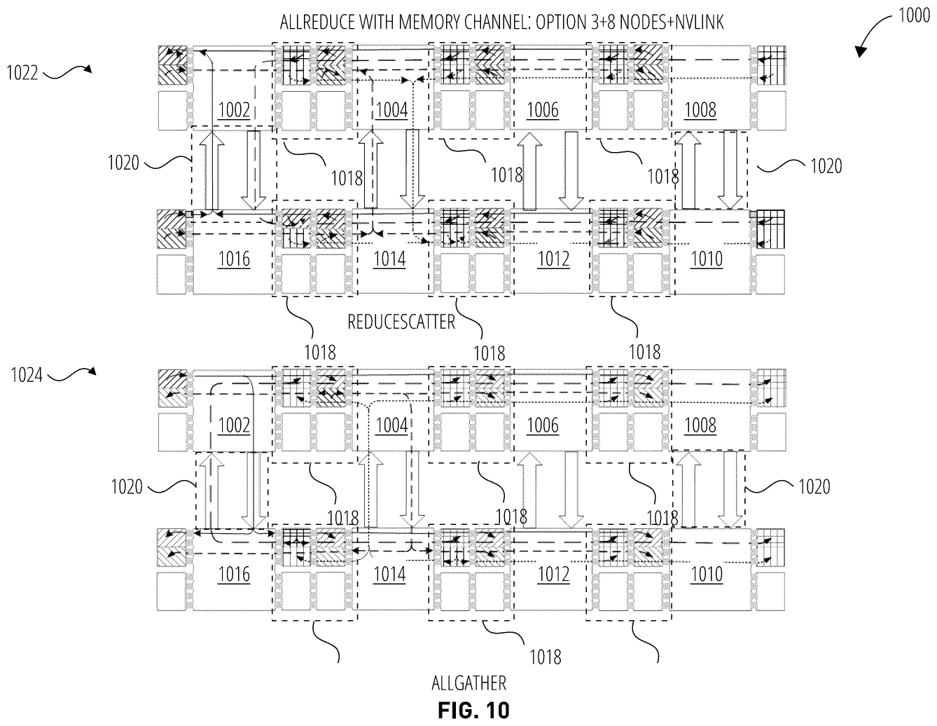

In at least one embodiment, the multi-port memory devices may directly connect to the two devices, such as the two GPUs. In at least one embodiment, an interposer (active or passive) may be used between the multi-port memory devices and the devices (e.g., GPUs). The embodiments described herein are scalable beyond a GPU box, as illustrated in the set of four GPUs in FIG. 1. The embodiments described herein may accommodate multiple GPU boxes within a server board. In at least one embodiment, a computing system may include eight nodes (e.g., eight GPUs) with communication channels with dual-port memory devices, such as illustrated in FIG. 9. In at least one embodiment, a computing system may include eight nodes (e.g., eight GPUs) with communication channels with the dual-port memory devices mixed with additional proprietary communication links, such as NVLinks, InfiniBand links, or the like, such as illustrated in FIG. 10.

FIG. 9 illustrates data flows in an all-reduce operation with a computing system 900 having eight nodes and dual-port memory devices as HBM channels (GPU connections) between the eight nodes according to at least one embodiment. It should be noted that ¼th of the model segments are shown in FIG. 9. Other model segments have similar operations. The computing system 900 includes a first node 902, a second node 904, a third node 906, a fourth node 908, a fifth node 910, a sixth node 912, a seventh node 914, and an eighth node 916. Between each pair of nodes, there is a set of communication channels 918, each communication channel (HBM) having multiple dual-port memory devices as described herein. In this embodiment, each port of the dual-port memory devices includes two sub-ports. Alternatively, the number of sub-ports is configurable.

The computing system 900 may perform an all-reduce operation by performing a reduce-scatter operation 920 and an all-gather operation 922. The different memory devices may operate in lock step to perform operations, such as a read, a write, a pass, a read-pass, a write-pass, a read-reduce-pass, and a read-reduce-write data.

In at least one embodiment, the eight nodes 902 to 916 are GPUs. The GPUs may be the same stock-keeping unit (SKU) or may be different SKUs with different HBM interfaces.

FIG. 10 illustrates data flows in an all-reduce operation with a computing system 1000 having eight GPUs, dual-port memory devices as HBM channels (GPU connections) between some GPUs, and additional communication links between other GPUs according to at least one embodiment. It should be noted that half of the model segments are shown in FIG. 9. The other half is symmetrical. The computing system 1000 includes a first node 1002, a second node 1004, a third node 1006, a fourth node 1008, a fifth node 1010, a sixth node 1012, a seventh node 1014, and an eighth node 1016. Between each pair of some nodes, there is a set of communication channels 1018, each communication channel (HBM) having multiple dual-port memory devices as described herein. In this embodiment, each port of the dual-port memory devices includes two sub-ports. Alternatively, the number of sub-ports is configurable. Between each pair of some nodes, there is a set of additional communication links 1020. The additional communication links 1020 may be NVLinks, InfiniBand links, Ethernet links, or the like. For example, the NVLink may provide 450 GB/s, while ⅛th of the HBM bandwidth is 250 GB/s. The overall flow is limited by the slowest link between a source node and a target node if there is no additional buffer. The HBMs on the left and right edges may be half the size of HBMs between GPUs.

The computing system 1000 may perform an all-reduce operation by performing a reduce-scatter operation 1022 and an all-gather operation 1024. The different memory devices may operate in lock step to perform operations, such as a read, a write, a pass, a read-pass, a write-pass, a read-reduce-pass, and a read-reduce-write data. The additional functions of read-reduce2-write, and read2 may be added to the base die. It should be noted that “read2” means two operands are read from the memory stack. It should be noted that “Read-reduce2-write” means one operand is read from the memory stack, two operands come from two ports, and three operands are reduced, and the result is written to the memory stack. In at least one embodiment, the node (GPU) may have the reduce function to perform the operation when passing data over the additional communication links 1020. The node (GPU) may route data among the HBMs (e.g., memory I/Os) and the additional communication links 1020 (e.g., NVLink I/Os).

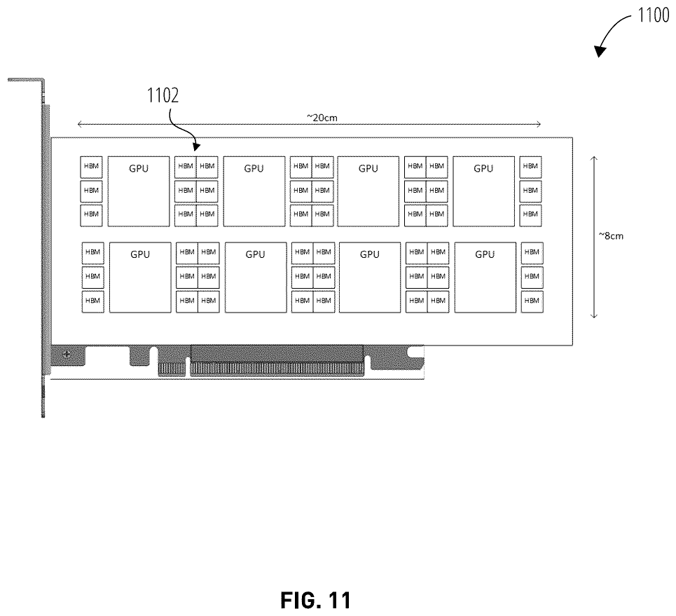

As described above, the dual-port memory devices used as communication channels between nodes may provide scalability in computing systems, such as illustrated in an expansion card of FIG. 11.

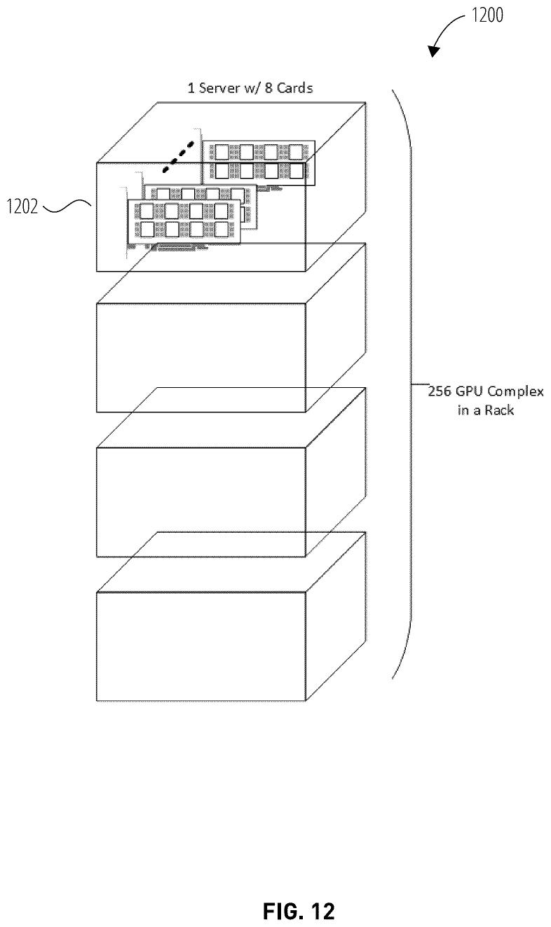

FIG. 11 illustrates an expansion card 1100 with eight GPUs and dual-port memory devices as HBM connections between the eight GPUs according to at least one embodiment. The expansion card 1100 may include the computing system 1000 of FIG. 10 with eight GPUs, where some of the GPUs are connected using HBM connections and other GPUs connected using additional communication links (not illustrated in FIG. 11). Each HBM connection (also referred to as a GPU connection) between two GPUs may be made with two dual-port memory devices described herein. The expansion card 1100 may be used in a computer, such as coupled to a motherboard having a central processing unit (CPU). The expansion card 1100 may have other numbers of GPUs and different configurations, such as described herein. The expansion card 1100 may be used with other expansion cards in a server. Multiple servers may be used in a rack, such as illustrated in FIG. 12.

FIG. 12 illustrates a rack 1200 with multiple servers with multiple expansion cards according to at least one embodiment. The rack 1200 may include multiple servers (four illustrated), each server including multiple expansion cards, such as described above with respect to FIG. 11. For example, a first server 1202 may include eight expansion cards coupled to a server board (e.g., server motherboard). The rack 1200 may include 256 GPUs, where there are four servers, each server having eight expansion cards, each expansion card having eight GPUs. Alternatively, the rack 1200 may have other numbers of servers and other numbers of expansion cards with different configurations of GPUs.

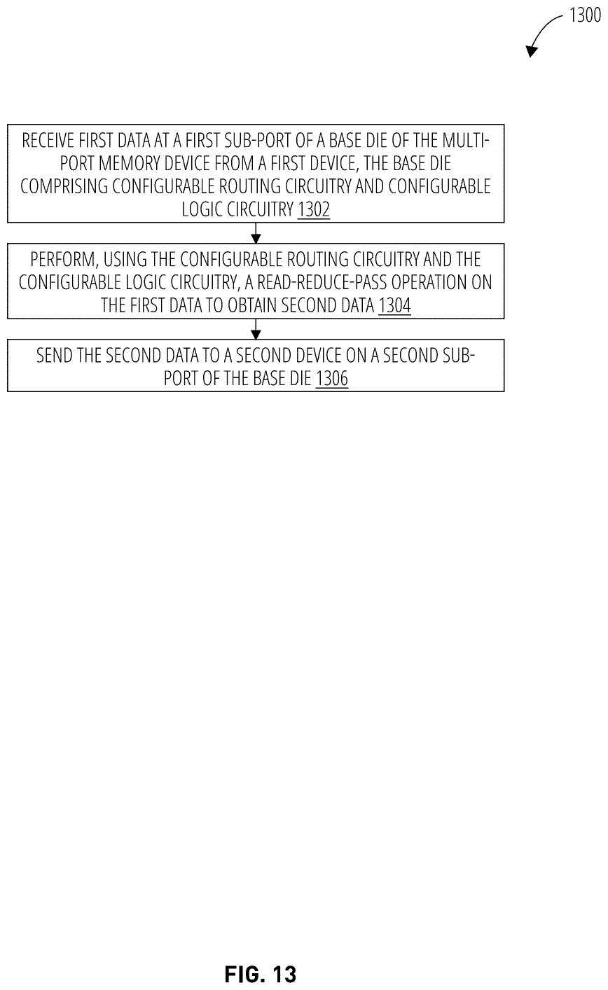

FIG. 13 is a flow diagram of a method 1300 for performing an operation on data received at a multi-port memory device according to at least one embodiment. The method 1300 may be performed by processing logic that may comprise hardware (e.g., circuitry, dedicated logic, programmable logic, microcode, etc.), software (e.g., instructions run on a processing device to perform hardware simulation), or a combination thereof. In one embodiment, the method 1300 is performed by any of the hardware described above with respect to FIG. 1 to FIG. 12. In one embodiment, the method 1300 is performed by a dual-port memory device 102 of FIG. 1, dual-port memory device 200 of FIG. 2, dual-port memory device 402 of FIG. 4, dual-port memory device 502 of FIG. 5, dual-port memory device 602 of FIG. 6, or dual-port memory device 702 of FIG. 7. The method 1300 may be performed by the memory device 800 of FIG. 8 or the memory device 820 of FIG. 8B. The method 1300 may be performed by the dual-port memory devices of the set of communication channels 918 of FIG. 9 or the set of communication channels 1018 of FIG. 10. The method 1300 may be performed by memory devices of the HBM connection 1102 of FIG. 11 or the first server 1202 of FIG. 12.

Referring to FIG. 13, the method 1300 begins with the processing logic receiving first data at a first sub-port of a base die of the multi-port memory device from a first device, the base die comprising configurable routing circuitry and configurable logic circuitry (block 1302). At block 1304, the processing logic performs, using the configurable routing circuitry and the configurable logic circuitry, a read-reduce-pass operation on the first data to obtain second data. At block 1306, the processing logic sends the second data to a second device on a second sub-port of the base die.

In a further embodiment, the processing logic receives third data at a third sub-port of the base die from the first device. The processing logic performs a read-reduce-write operation on the third data. In other embodiments, the processing logic may perform at least one of a read operation, a write operation, a read-pass operation, a write-pass operation, a read-reduce-pass operation, or a read-reduce-write operation on third data.

It is to be understood that the above description is intended to be illustrative, and not restrictive. Many other implementations will be apparent to those of skill in the art upon reading and understanding the above description. The scope of the disclosure should, therefore, be determined with reference to the appended claims, along with the full scope of equivalents to which such claims are entitled.

In the above description, numerous details are set forth. It will be apparent, however, to one skilled in the art, that the aspects of the present disclosure may be practiced without these specific details. In some instances, well-known structures and devices are shown in block diagram form, rather than in detail, in order to avoid obscuring the present disclosure.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “receiving,” “determining,” “selecting,” “storing,” “setting,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present disclosure also relates to an apparatus for performing the operations herein. This apparatus may be specially constructed for the required purposes, or it may comprise a general-purpose computer selectively activated or reconfigured by a computer program stored in the computer. Such a computer program may be stored in a computer-readable storage medium, such as, but not limited to, any type of disk including floppy disks, optical disks, CD-ROMs, magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems may be used with programs in accordance with the teachings herein, or it may prove convenient to construct more specialized apparatus to perform the required method steps. The required structure for a variety of these systems will appear as set forth in the description. In addition, aspects of the present disclosure are not described with reference to any particular programming language. It will be appreciated that a variety of programming languages may be used to implement the teachings of the present disclosure as described herein.

Aspects of the present disclosure may be provided as a computer program product, or software, that may include a machine-readable medium having stored thereon instructions, which may be used to program a computer system (or other electronic devices) to perform a process according to the present disclosure. A machine-readable medium includes any procedure for storing or transmitting information in a form readable by a machine (e.g., a computer). For example, a machine-readable (e.g., computer-readable) medium includes a machine (e.g., a computer) readable storage medium (e.g., read-only memory (“ROM”), random access memory (“RAM”), magnetic disk storage media, optical storage media, flash memory devices, etc.).

Typically, such “fragile” data is delivered sequentially from the data source to each of its destinations. The transfer may include transmitting or delivering the data from the source to a single destination and waiting for an acknowledgment. Once the acknowledgment has been received, the source then commences the delivery of data to the next destination. The time required to complete all the transfers may potentially exceed the lifespan of the delivered data if there are many destinations or there is a delay in reception for one or more transfer acknowledgments. This has traditionally been addressed by introducing multiple timeout/retry timers and complicated scheduling logic to ensure timely completion of all the transfers and identify anomalous behavior.

In at least one embodiment, the situation may be improved by either broadcasting the data to all the destinations at once, like a multi-cast transmission in Ethernet. This may decouple the data delivery and acknowledgment without delaying the delivery of data by a previous destination's delivery acknowledgment. These approaches may provide some following benefits, as well as others. Broadcasting the data to all destinations at once may remove any limit to the number of destinations that may be supported. The control logic may be simplified. For example, there may be a single time to track the lifespan of data and a single register to track delivery acknowledgment reception. In one embodiment, an incomplete delivery is simply indicated by the register not being fully populated by 1′s (or 0′s if the convention is reversed) at the end of the data timeout period.

It is to be understood that the above description is intended to be illustrative and not restrictive. Many other implementations will be apparent to those of skill in the art upon reading and understanding the above description. Therefore, the disclosure scope should be determined with reference to the appended claims, along with the full scope of equivalents to which such claims are entitled.

In the above description, numerous details are set forth. It will be apparent, however, to one skilled in the art that the aspects of the present disclosure may be practiced without these specific details. In some instances, well-known structures and devices are shown in block diagram form rather than in detail to avoid obscuring the present disclosure.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to the desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

However, it should be borne in mind that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “receiving,” “determining,” “selecting,” “storing,” “setting,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

The present disclosure also relates to an apparatus for performing the operations herein. This apparatus may be specially constructed for the required purposes, or it may comprise a general-purpose computer selectively activated or reconfigured by a computer program stored in the computer. Such a computer program may be stored in a computer-readable storage medium, such as, but not limited to, any type of disk, including floppy disks, optical disks, CD-ROMs, and magnetic-optical disks, read-only memories (ROMs), random access memories (RAMs), erasable programmable ROMs (EPROMs), electrically erasable programmable ROMs (EEPROMs), magnetic or optical cards, or any type of media suitable for storing electronic instructions, each coupled to a computer system bus.

The algorithms and displays presented herein are not inherently related to any particular computer or other apparatus. Various general-purpose systems may be used with programs in accordance with the teachings herein, or it may prove convenient to construct more specialized apparatuses to perform the required method steps. The required structure for a variety of these systems will appear as set forth in the description. In addition, aspects of the present disclosure are not described with reference to any particular programming language. It will be appreciated that a variety of programming languages may be used to implement the teachings of the present disclosure as described herein.

Aspects of the present disclosure may be provided as a computer program product, or software, that may include a machine-readable medium having stored thereon instructions, which may be used to program a computer system (or other electronic devices) to perform a process according to the present disclosure. A machine-readable medium includes any procedure for storing or transmitting information in a form readable by a machine (e.g., a computer). For example, a machine-readable (e.g., computer-readable) medium includes a machine (e.g., a computer) readable storage medium (e.g., read-only memory (“ROM”), random access memory (“RAM”), magnetic disk storage media, optical storage media, flash memory devices, etc.).

What is claimed is:

1. A dynamic random access memory (DRAM) device comprising:
one or more stacks of memory dies;
a base die having at least two ports, wherein each of the at least two ports comprises one or more sub-ports, and wherein each sub-port has one or more channels operating in lockstep; and
a configurable logic block on the base die to perform an operation on data from the one or more sub-ports or the one or more stacks of memory dies.

2. The DRAM device of claim 1, wherein a number of the one or more sub-ports is configurable.

3. The DRAM device of claim 1, wherein each of the one or more stacks of memory device is accessible by each of the one or more sub-ports.

4. The DRAM device of claim 1, wherein the configurable logic block is to perform a parallel computing operation.

5. The DRAM device of claim 1, wherein the configurable logic block is to perform at least one of a reduce operation, an all-reduce operation, a reduce-scatter operation, a gather operation, an all-gather operation, a scatter operation, a broadcast operation, a barrier operation, a prefix sum operation, an all-to-all operation, a scatter-gather operation, a collective communication operation, a parallel prefix operation, or a map-reduce operation.

6. The DRAM device of claim 1, wherein the configurable logic block is to perform at least a portion of an all-reduce operation comprising a reduce-scatter operation and an all-gather operation.

7. The DRAM device of claim 1, further comprising configurable routing circuitry on the base die to route data from the one or more sub-ports or the one or more stacks of memory dies.

8. The DRAM device of claim 1, wherein the at least two ports comprise:
a first port coupled to a first graphics processing unit (GPU); and
a second port coupled to a second GPU.

9. The DRAM device of claim 8, wherein:
the first port comprises a first sub-port and a second sub-port; and
the second port comprises a third sub-port and a fourth sub-port.

10. The DRAM device of claim 8, wherein:
the first port comprises a first sub-port, a second sub-port, a third sub-port; and
the second port comprises a fourth sub-port, a fifth sub-port, and a sixth sub-port.

11. A memory device comprising:
a first memory stack; and
a first base die comprising a first port, a second port, first configurable routing circuitry, and first configurable logic circuitry, wherein the first memory stack is accessible by the first port and the second port via the first configurable routing circuitry, wherein the first configurable logic circuitry is configured to perform an operation on data from at least one of the first port, the second port, or the first memory stack.

12. The memory device of claim 11, wherein the first port is programmably divided into a first sub-port and a second sub-port, wherein the first sub-port comprises the first configurable routing circuitry and the first configurable logic circuitry, wherein the second sub-port comprises second configurable routing circuitry and second configurable logic circuitry, wherein the first configurable logic circuitry is configured to perform the operation on data from at least one of the first sub-port or the first memory stack, and wherein the second configurable logic circuitry is configured to perform the operation on data from at least one of the second sub-port or the first memory stack.

13. The memory device of claim 12, further comprising:
a second memory stack; and
a second base die comprising:
a third sub-port with third configurable routing circuitry and third configurable logic circuitry; and
a fourth sub-port with fourth configurable routing circuitry and fourth configurable logic circuitry, wherein:
the first memory stack is accessible by the first sub-port, the second sub-port, the third sub-port, and the fourth sub-port;
the second memory stack is accessible by the first sub-port, the second sub-port, the third sub-port, and the fourth sub-port;
the third configurable logic circuitry is to perform the operation on data from at least one of the third sub-port or the second memory stack; and
the fourth configurable logic circuitry is to perform the operation on data from at least one of the fourth sub-port or the second memory stack.

14. The memory device of claim 12, further comprising:
a second memory stack, wherein the first base die further comprises:
a third sub-port with third configurable routing circuitry and third configurable logic circuitry; and
a fourth sub-port with fourth configurable routing circuitry and fourth configurable logic circuitry, wherein:
the first memory stack is accessible by the first sub-port, the second sub-port, the third sub-port, and the fourth sub-port;
the second memory stack is accessible by the first sub-port, the second sub-port, the third sub-port, and the fourth sub-port;
the third configurable logic circuitry is to perform the operation on data from at least one of the third sub-port or the second memory stack; and
the fourth configurable logic circuitry is to perform the operation on data from at least one of the fourth sub-port or the second memory stack.

15. The memory device of claim 11, wherein the operation is at least one of a reduce operation, an all-reduce operation, a reduce-scatter operation, a gather operation, an all-gather operation, a scatter operation, a broadcast operation, a barrier operation, a prefix sum operation, an all-to-all operation, a scatter-gather operation, a collective communication operation, a parallel prefix operation, or a map-reduce operation.

16. A communication channel coupled between a first device and a second device, wherein the communication channel comprises:
a dynamic random access memory (DRAM) device comprising:
a first base die having a first port coupled to the first device, wherein the first port comprises one or more sub-ports;
a first memory stack coupled to the first base die;
a first configurable logic block on the first base die;
a second base die having a second port coupled to the second device, wherein the second port comprises one or more sub-ports, wherein the second base die is coupled to the first base die;
a second memory stack coupled to the second base die; and
a second configurable logic block on the second base die, wherein:
the first configurable logic block is to perform a first operation on first data from
the one or more sub-ports of the first port, the one or more sub-ports of the second port,
the first memory stack, or the second memory stack; and
the second configurable logic block is to perform a second operation on second data from the one or more sub-ports of the first port, the one or more sub-ports of the second port, the first memory stack, or the second memory stack.

17. The communication channel of claim 16, wherein the first device is a first graphics processing unit (GPU), and the second device is a second GPU.

18. The communication channel of claim 16, wherein the first memory stack is accessible by the first device or the second device, and wherein the second memory stack is accessible by the first device or the second device.

19. The communication channel of claim 16, wherein a number of the one or more sub-ports is configurable.

20. The communication channel of claim 16, wherein the first operation is at least one of a reduce-scatter operation or an all-gather operation of an all-reduce operation.
